(19) United States
(12) Patent Application Publication
(10) Pub. No.: US 2008/0070410 A1
(43) Pub. Date: Mar. 20, 2008

(54) Method for manufacturing capacitor using system in package

(75) Inventor: Jae Won Han, Suwon-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu HiTek Co., Ltd.

(21) Appl. No.: 11/898,436

(22) Filed: Sep. 12, 2007

(30) Foreign Application Priority Data
Sep. 13, 2006 (KR) 10-2006-0088434

(51) Int. Cl. H01L 21/44

(52) U.S. Cl. 438/675; 257/E21.476

(57) ABSTRACT

A method for manufacturing a capacitor is provided. The method includes: forming a first hole, depositing a barrier metal on an inner wall of the first hole to form a first electrode. The method further includes forming a second hole and bottom electrode-hole aligned with the first hole, forming a second electrode and a bottom electrode, forming a top electrode, and performing a back grind process to expose the first electrode under the silicon substrate.

This application claims the benefit of priority to Korean Patent Application No. 10-2006-088434, filed on Sep. 13, 2006, the entire contents of which are incorporated herein by reference.

### BACKGROUND

1. Technical Field

The present invention relates to a method for manufacturing a capacitor using a System In a Package (SIP), and more particularly to a method for separately manufacturing a capacitor and a transistor, the capacitor connecting the transistor using the SIP.

2. Related Art

SiO₂/Si₃N₄-based dielectric materials are commonly used to form a dielectric layer of a capacitor. Capacitors may typically be classified into a Polysilicon-Insulator-Polysilicon type (PIP-type) capacitor or a Metal-Insulator-Metal type (MIM-type) capacitor, according to the materials of electrodes of the capacitor. In contrast to a Metal-Oxide-Semiconductor (MOS) capacitor or a junction capacitor, a thin-film capacitor, such as the PIP-type or MIM-type capacitor, may have a property independent of bias voltages. Accordingly, the thin-film capacitor has been widely used for analog-type products, which require capacitors of high precision.

In general, it is difficult to manufacture a MIM-type capacitor to have a capacitance per unit area greater than that of the PIP-type capacitor. However, the MIM-type capacitor has a superior Voltage Coefficient for Capacitor (VCC) and a Temperature Coefficient for Capacitor (TCC) characteristics as compared to the PIP-type capacitor. Thus, it is preferable to adopt a MIM-type capacitor for high-precision analog products.

As the integration of semiconductor devices increases, a conventional Metal-Insulator-Semiconductor-type (MIS-type) capacitor, which may include a low dielectric layer between a dielectric layer and a polysilicon layer, may be unable to acquire a desired capacitance. Therefore, there is a need to develop an improved MIM-type capacitor capable of substituting the MIS-type capacitor.

However, the aforementioned capacitor manufacturing process may have a negative influence on thermal and chemical factors of other device components. As the size of the capacitor becomes smaller, there is a limitation in reducing the thickness of an insulation layer of the capacitor. In addition, the space capable of adjusting the area of a metal electrode of the capacitor is also small. Accordingly, it is difficult to acquire a desired capacitance value for the capacitor.

Also, the conventional method for manufacturing the capacitor cannot cope with a semiconductor device having a complicated structure, because the semiconductor device may require a variety of capacitance values in various ways.

### SUMMARY

Accordingly, embodiments consistent with the present invention are directed to a method for manufacturing a capacitor using an SIP that may obviate one or more problems due to limitations and disadvantages in the related art.

One feature consistent with the present invention is to provide a method for manufacturing a semiconductor device, which separately manufactures a capacitor and a transistor, and connects the capacitor to the transistor using an SIP.

Additional features consistent with the present invention will be set forth in part in the following description and in part being apparent to those having ordinary skill in the art upon examination of the following or learned from practice of the present invention.

In one embodiment, there is provided a method for manufacturing a capacitor. The method comprises: forming a first electrode, wherein forming the first electrode comprises: forming a first hole in a semiconductor substrate by patterning the semiconductor substrate; forming a barrier metal on an inner wall of the first hole; forming a first metal material in the first hole; and planarizing the first metal material; forming a first insulation layer on the semiconductor substrate including the first electrode, patterning the first insulation layer to form a second hole aligned with the first hole and a bottom electrode hole; forming a second electrode, wherein forming the second electrode comprises: forming a barrier metal on an inner wall of the second hole and the bottom electrode hole; forming a second metal material in the second hole and the bottom electrode; and planarizing the second metal material; forming a dielectric layer on the first insulation layer; forming top electrodes, wherein forming top electrodes comprises: forming a second insulation layer on the dielectric insulation layer; patterning the second insulation layer to form a plurality of top electrode holes; forming a barrier metal on inner walls of the top electrode holes; forming a third metal material in the top electrode holes; and planarizing the third metal material; forming a passivation layer on the second insulation layer; and performing a back grind process to expose the first electrode at a bottom surface of the semiconductor substrate.

It is to be understood that both the foregoing general description and the following detailed description consistent with the present invention are exemplary and explanatory, and are solely intended to provide further explanation of the invention as claimed.

### BRIEF DESCRIPTION OF THE DRAWINGS

The accompanying drawings, which are included to provide a further understanding of the present invention and are incorporated to constitute a part of this application, illustrate embodiment(s) consistent with the present invention, and, together with the detailed description, serve to explain the principle of the present invention. In the drawings:

FIGS. 1A to 1E are cross-sectional views illustrating a method for manufacturing a capacitor using an SIP, consistent with the present invention.

### DETAILED DESCRIPTION

Reference will now be made in detail to the preferred embodiments consistent with the present invention, examples of which are illustrated in the accompanying drawings. Wherever possible, the same reference numbers will be used throughout the drawings to refer to the same or like parts.

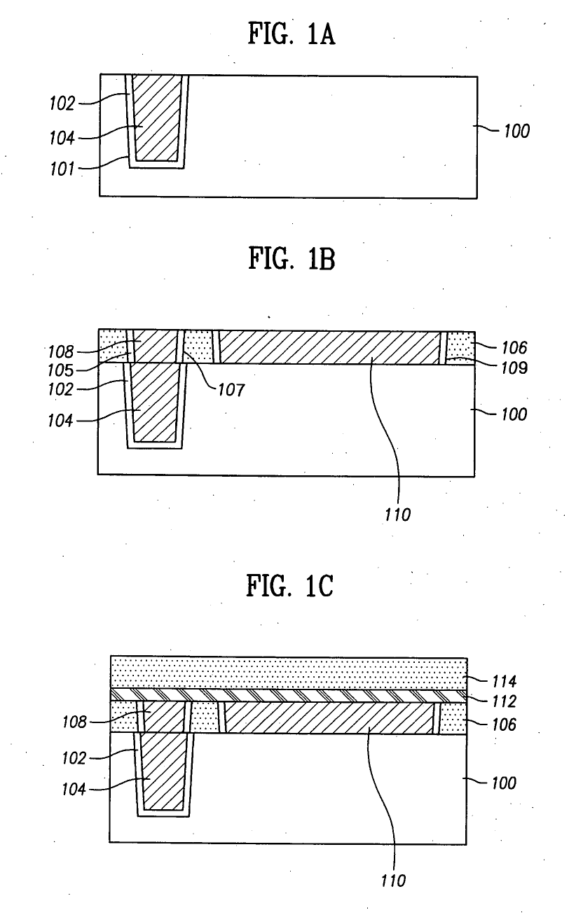

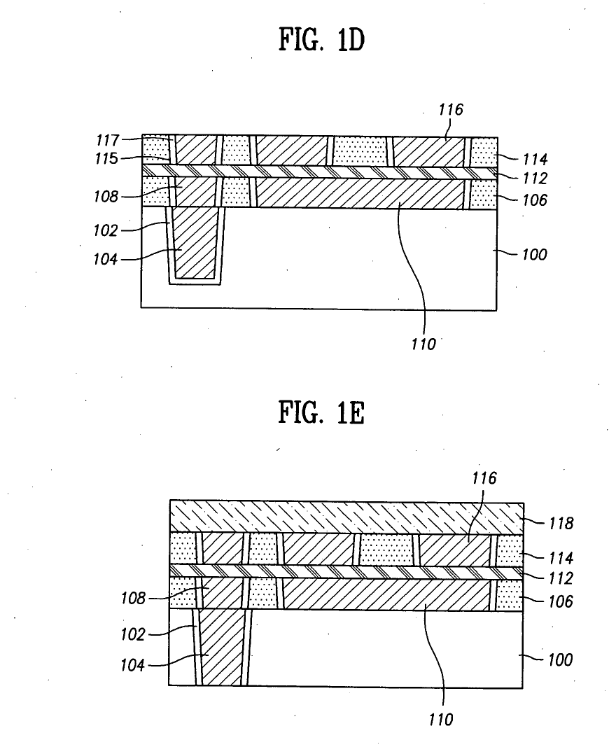

FIGS. 1A to 1E are cross-sectional views illustrating a method for manufacturing a capacitor using an SIP consistent with the present invention.

Referring to FIG. 1A, a semiconductor substrate 100 is patterned to form a first hole 101. In this case, first hole 101 has a depth of about 50˜500 μm, and a critical dimension (CD) of about 1˜10 μm. Subsequently, a barrier metal 102 may be formed on an inner wall of first hole 101 to have a thickness of about 20˜1000 Å using a metal thin film deposition method, such as Physical Vapor Deposition (PVD), Sputtering, Evaporation, Laser Ablation, Atomic Layer Deposition (ALD), Chemical Vapor Deposition (CVD), etc. Barrier metal 102 may comprise Ti, TiN, Ti/TiN, Ta, TaN, Ta/TaN, TaN/Ta, Co, Co compound, Ni, Ni compound, W, W compound, or nitride materials.

Thereafter, a metal material (e.g., Al, Al compound, Cu, Cu compound, W, or W compound) having a thickness of about 50˜900 μm, on the basis of a flat panel, may be formed in first hole 101 using a metal thin film deposition method, such as PVD, Sputtering, Evaporation, Laser Ablation, Electron Copper Plating (ECP), ALD, CVD, etc. The metal material is planarized using a Chemical Mechanical Polishing (CMP) process or an etch back process, such that a first electrode 104 is formed.

As shown in FIG. 1B, a first insulation layer 106 is deposited on semiconductor substrate 100 including first electrode 104 using an electric furnace, a CVD apparatus, or a PVD apparatus. In this case, first insulation layer 106 may be formed to have a thickness of about 50˜10000 Å by depositing an insulating material, such as SiO₂, borophosphosilicate glass (BPSG), tetraethyl orthosilicate (TEOS), SiN, or a Low-k material. Thereafter, first insulation layer 106 is patterned, and a second hole 107 aligned with first hole 101 and a bottom electrode hole 109 are formed. A barrier metal 105 may be formed on inner walls of second hole 107 and bottom electrode hole 109 to have a thickness of about 20˜1000 Å using a deposition process, such as PVD, Sputtering, Evaporation, Laser Ablation, ALD, CVD, etc. Barrier metal 105 may comprise Ti, TiN, Ti/TiN, Ta, TaN, Ta/TaN, TaN/Ta, Co, Co compound, Ni, Ni compound, W, W compound, or nitride materials.

Thereafter, a metal material (e.g., Al, Al compound, Cu, Cu compound, W, and W compound) having a thickness of about 100˜15000 Å, on the basis of a flat panel, may be formed in second hole 107 and bottom electrode hole 109 using a metal thin film deposition method, such as PVD, Sputtering, Evaporation, Laser Ablation, ECP, ALD, CVD, etc. The metal material is planarized by a Chemical Mechanical Polishing (CMP) process or an etch back process, such that second electrode 108 and bottom electrode 110 are formed.

As shown in FIG. 1C, a dielectric layer 112 is deposited on first insulation layer 106 including second electrode 108 and bottom electrode 110 to have a thickness of about 5˜5000 Å using an electric furnace, a CVD apparatus, or a PVD apparatus. Dielectric layer 112 may comprise SiN, SiO₂, BPSG, or TEOS. Further, a second insulation layer 114 having a thickness of about 50˜10000 Å is formed on dielectric layer 112 using a CVD method or a PVD method. Second insulation layer 114 may comprise SiO₂, BPSG, TEOS, SiN, or a Low-k material.

As shown in FIG. 1D, second insulation layer 114 is patterned to form a plurality of top electrode holes 115. In this case, top electrode holes 115 may have a depth of about 50˜10000 Å. Thereafter, a barrier metal 117 may be formed on inner walls of top electrode holes 115 to have a thickness of about 20˜1000 Å using a deposition method, such as PVD, Sputtering, Evaporation, Laser Ablation, ALD, CVD, etc. Barrier metal 117 may comprise Ti, TiN, Ti/TiN, Ta, TaN, Ta/TaN, TaN/Ta, Co, Co compound, Ni, Ni compound, W, W compound, or nitride materials.

Thereafter, a metal material (e.g., Al, Al compound, Cu, Cu compound, W, and W compound) having a thickness of about 100˜15000 Å, on the basis of a flat panel, may be formed in top electrode holes 115 using a metal thin film deposition method, such as PVD, Sputtering, Evaporation, Laser Ablation, ECP, ALD, CVD, etc. The metal material is planarized using a CMP process or an etch back process, such that top electrodes 116 are formed.

As shown in FIG. 1E, a passivation layer 118 having a thickness of about 0.3˜5 μm is deposited on top electrodes 116 and second insulation layer 114 using an electric furnace, a CVD apparatus, or a PVD apparatus. Passivation layer 118 may comprise SiO₂, BPSG, TEOS, or SiN. Thereafter, a back grind process is performed, such that first electrode 104 is exposed at a bottom surface of semiconductor substrate 100. Following the back grind process, semiconductor substrate 100 may have a thickness of about 50˜500 μm.

As may be apparent from the above description, the present invention may provide a method for manufacturing a capacitor using an SIP, so as to simplify the design and the manufacturing process of a semiconductor device. Further, capacitor information can be configured in terms of library data.

In one embodiment, the present invention may reduce the degree of wafer damage caused by the MIM or PIP process, and can guarantee a variety of capacitance values.

It will be apparent to those skilled in the art that various modifications and variations can be made in the present invention without departing from the spirit and/or scope of the present invention. Thus, it is intended that the present invention covers the modifications and variations thereof provided they fall within the scope of the appended claims and their equivalents.

What is claimed is:

1. A method for manufacturing a capacitor, comprising:
forming a first electrode, wherein forming the first electrode comprises:
forming a first hole in a semiconductor substrate by patterning the semiconductor substrate;
forming a barrier metal on an inner wall of the first hole;
forming a first metal material in the first hole; and
planarizing the first metal material;
forming a first insulation layer on the semiconductor substrate including the first electrode, patterning the first insulation layer to form a second hole aligned with the first hole and a bottom electrode hole;
forming a second electrode, wherein forming the second electrode comprises:
forming a barrier metal on an inner wall of the second hole and the bottom electrode hole;
forming a second metal material in the second hole and the bottom electrode; and
planarizing the second metal material;
forming a dielectric layer on the first insulation layer;
forming top electrodes, wherein forming top electrodes comprises:
forming a second insulation layer on the dielectric insulation layer;
patterning the second insulation layer to form a plurality of top electrode holes;
forming a barrier metal on inner walls of the top electrode holes;
forming a third metal material in the top electrode holes; and
planarizing the third metal material;
forming a passivation layer on the second insulation layer; and
performing a back grind process to expose the first electrode at a bottom surface of the semiconductor substrate.

2. The method according to claim 1, wherein the first hole has a depth of about 50˜500 μm, and a critical dimension (CD) of about 1˜10 μm.

3. The method according to claim 1, wherein the barrier metal includes at least one of Ti, TiN, Ti/TiN, Ta, TaN, Ta/TaN, TaN/Ta, Co, Co compound, Ni, Ni compound, W, W compound, and a nitride material, and is deposited with a thickness of about 20˜1000 Å using a metal thin film deposition method, the metal thin film deposition method including Physical Vapor Deposition (PVD), Sputtering, Evaporation, Laser Ablation, Atomic Layer Deposition (ALD), or Chemical Vapor Deposition (CVD).

4. The method according to claim 1, wherein:
the first metal material comprises at least one of Al, Al compound, Cu, Cu compound, W, and W compound, the first metal material being formed to have a thickness of about 50˜900 μm, on the basis of a flat panel, in the first hole using a metal thin film deposition method, the metal thin film deposition method including Physical Vapor Deposition (PVD), Sputtering, Evaporation, Laser Ablation, Electro Copper plating (ECP), Atomic Layer Deposition (ALD), and Chemical Vapor Deposition (CVD); and
wherein planarizing the metal material comprises performing a Chemical Mechanical Polishing (CMP) process or an etch back process.

5. The method according to claim 1, wherein the first insulation layer includes at least one of SiO₂, borophosphosilicate glass (BPSG), tetraethyl orthosilicate (TEOS), SiN, and a Low-k material, and is formed to have a thickness of about 50˜10000 Å using an electric furnace, a Chemical Vapor Deposition (CVD) apparatus, or a Physical Vapor Deposition (PVD) apparatus.

6. The method according to claim 1, wherein:
the second metal material comprises at least one of Al, Al compound, Cu, Cu compound, W, and W compound, the second metal material being formed to have a thickness of about 100˜15000 μm, on the basis of a flat panel, in the second hole and the bottom electrode hole using a metal thin film deposition method, the metal thin film deposition method including Physical Vapor Deposition (PVD), Sputtering, Evaporation, Laser Ablation, Electro Copper plating (ECP), Atomic Layer Deposition (ALD), and Chemical Vapor Deposition (CVD); and
wherein planarizing the second metal material comprises performing a Chemical Mechanical Polishing (CMP) process or an etch back process.

7. The method according to claim 1, wherein the dielectric layer includes at least one of SiN, SiO₂, borophosphosilicate glass (BPSG), and tetraethyl orthosilicate (TEOS), and is formed to have a thickness of about 5˜5000 Å using a metal thin film deposition method in an electric furnace, a Chemical Vapor Deposition (CVD) apparatus, or a Physical Vapor Deposition (PVD) apparatus.

8. The method according to claim 1, wherein the second insulation layer includes at least one of SiO₂, borophosphosilicate glass (BPSG), tetraethyl orthosilicate (TEOS), SiN, and a Low-K material, and is formed to have a thickness of about 50˜10000 Å using a metal thin film deposition method including Chemical Vapor Deposition (CVD) or Physical Vapor Deposition (PVD).

9. The method according to claim 1, wherein the passivation layer includes at least one of SiO₂, borophosphosilicate glass (BPSG), tetraethyl orthosilicate (TEOS), and SiN, and is formed to have a thickness of about 0.3˜5 μm using a metal thin film deposition method in an electric furnace, a Chemical Vapor Deposition (CVD) apparatus, or a Physical Vapor Deposition (PVD) apparatus.
